(19) United States
(12) Patent Application Publication
(10) Pub. No.: US 2003/0124783 A1
(43) Pub. Date: Jul. 3, 2003

(54) System for creating ultra-shallow dopant profiles

(76) Inventors: Antonio L. P. Rotondaro, Dallas, TX (US); James J. Chambers, Dallas, TX (US)

Correspondence Address: TEXAS INSTRUMENTS INCORPORATED, P O BOX 655474, M/S 3999, DALLAS, TX, 75265

(21) Appl. No.: 10/319,155

(22) Filed: Dec. 13, 2002

Related U.S. Application Data
(60) Provisional application No. 60/344,669, filed on Dec. 28, 2001.

(51) Int. Cl. H01L 21/336; H01L 21/8234

(52) U.S. Cl. 438/197; 438/301; 438/514; 438/526

(57) ABSTRACT

A system for fabricating an integrated circuit having a gate is disclosed, in which high-density material (20) is deposited on a substrate (10) at or about a gate (30) and the adjacent lightly doped drain is implanted using high implantation energy through the high density material to create a shallow drain (50).

### PRIORITY CLAIM

This patent application claims priority of U.S. Provisional Application No. 60/344,669, filed on Dec. 28, 2001.

### TECHNICAL FIELD OF THE INVENTION

The present invention relates in general to the field of integrated circuits, and more particularly, to formation of ultra-shallow dopant profiles for advanced CMOS processing.

### BACKGROUND OF THE INVENTION

Without limiting the scope of the invention, its background is described in connection with the formation of CMOS devices, as an example.

In the field of semiconductor production, the manufacturing cost of a given integrated circuit is dependent largely upon the chip area required to implement desired functions. The chip area is defined by the geometries and sizes of the active components disposed in the wafer substrate. Active components include gate electrodes in metal-oxide semiconductors (MOS) and diffused regions such as MOS source and drain regions and bipolar emitters, collectors and base regions.

A challenge with current CMOS fabrication and device formation, due to scaling, concerns achieving proper implantation depth of lightly doped drain (LDD) junctions. One method to address this problem has been the use of low energy implantation. A problem with low energy implantation is the lack of consistency encountered during the implantation process across a wafer and across substrate lots.

What is therefore needed is a method of making ultra-shallow dopant profiles that are formed consistently and with reduced steps using existing process equipment, processes and workflows. A need has also arisen for a simplified process for forming ultra-shallow dopant profiles that are economical to make using existing techniques and materials.

### SUMMARY OF THE INVENTION

The present invention provides a system for producing a source/drain region having an ultra-shallow dopant profile. Integrated circuits may be formed using the present invention in a consistent manner and with reduced steps using existing process equipment, processes and workflows. The simplified processes of the present invention allow for the formation of ultra-shallow dopant profiles (e.g., light doped drains) that are economical to make using existing techniques and materials.

Specifically, the present invention provides a method of fabricating an integrated circuit having a gate. A high-density material is deposited on a substrate, at or about the gate, and the adjacent lightly doped drain is implanted through the high-density material to create a shallow drain using high implantation energy.

### BRIEF DESCRIPTION OF THE DRAWINGS

For a more complete understanding of the features and advantages of the present invention, reference is now made to the detailed description of the invention along with the accompanying figures in which corresponding numerals in the different figures refer to corresponding parts and in which:

FIG. 1 is a cross section of a mixed voltage device according to the present invention;

FIG. 2 is a cross sectional view illustrating a processing step for LDD implantation according to the present invention;

FIG. 3 is a cross sectional view of an LDD implanted source/drain according to the present invention; and

FIG. 4 is a graph illustrating a comparison of the implantation depth at a constant implantation energy, using Hf silicate and silicon oxide as implant screens.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention and are not to delimit the scope of the invention.

The present invention is described in conjunction with a digital signal processor (DSP), however, it may be used with any other type of device. A DSP is used to illustrate the invention, but the invention may be used in other types of non-memory, mixed DSP-memory, memory or other circuits.

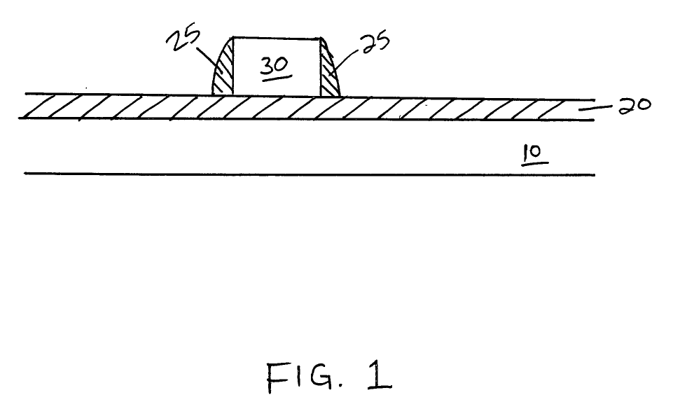

One embodiment of the present invention is described now in reference to FIG. 1. A substrate 10 is provided, and a high-density material 20 that also forms a gate dielectric is disposed on substrate 10. The substrate 10 is preferably p-type in conductivity, but n-type substrates may also be used. The high-density material may be, e.g., an Hf silicate, HfO₂, HfSiOₓ, Zirconium silicates and oxides, aluminum oxides, HfON, HfSiON, and combinations thereof, and is generally on the order of 1 to 10 nm thick. High-density material 20 generally has a high dielectric constant. The high-density material 20 may act as a replacement for the screening oxide during implantation, and may even be a dielectric material that serves as a high-density mask during implantation and as the gate dielectric. The gate structure 30, disposed upon the gate dielectric 20, may have sidewalls 25.

The high-density material is generally a high-K dielectric material. High-K as used herein refers to a dielectric material having a dielectric constant greater than 3.9. The high-density material may be formed in a layer that typically includes an oxygen-containing high-K dielectric material (e.g., Ta₂O₅, HfO₂, TiO₂, CeO₂, or HfSiO₄). However, a layer of high-density material may alternatively include a high-K material that is formed using a process that allows oxygen from another source to enter the environment. The thickness of high-K high-density material layer may be on the order of 10 to 110 Angstroms thick.

Other high-density materials that may be used in accordance with the present invention include, for example, Hf silicate, HfO₂, HfSiOₓ, Zirconium silicates and oxides, aluminum oxides, HfON, HfSiON, and combinations thereof, deposited using, for example, a low-pressure chemical-vapor deposition (LPCVD) process or a physical-vapor deposition (PVD) process such as evaporation or sputtering. High-density material 20 may be deposited either by a conformal or a partially conformal deposition process. Generally, a partially conformal PVD or CVD process is used to deposit a thinner high-density material on all surfaces and features on a substrate. The PVD processes, such as evaporation and sputtering, usually deposit material layers with partial conformality (typically 20% to 70%). CVD process parameters may also be adjusted in order to achieve reduced deposition conformalities (e.g., 30% to 85%). A thin (10 to 110 Angstroms thick) conformal high-density material may be formed using low-pressure chemical-vapor deposition (CVD) or plasma enhanced chemical-vapor deposition (PECVD).

One advantage of using an Hf silicate, HfO₂, HfSiOₓ, Zirconium silicates and oxides, aluminum oxides, HfON, HfSiON, and combinations thereof, as the high-density material 20, is that the same process equipment, processes and workflows used in existing products may also be used to create the lightly doped drain (LDD) of the present invention. The present invention also provides a simplified process for forming ultra-shallow dopant profiles that are economical to make, due to the use of existing techniques and materials.

Substrate 10 may be made of, for example, silicon, gallium arsenide, silicon on insulator (SOI) structures, epitaxial formations, germanium, germanium silicon, polysilicon, amorphous silicon, or like substrates, semi-conductive or conductive. Substrate 10 is typically made of single crystal silicon, and is usually lightly doped with, for example, Boron, Phosphorous or Arsenic atoms.

The gate material of structure 30 may be, e.g., polycrystalline silicon (“poly” or “polysilicon”). It may be epitaxial silicon, polycrystalline silicon germanium, or it may include metallic layers (e.g., metal gates). The substrate may also include isolation structures between the regions for forming the different gate structures 30. These isolation structures may comprise an oxide or some other insulator. The purpose of the isolation structure is to isolate the active devices from one another on the substrate. Once formed, the substrate may contain wells that will be of the opposite conductivity type when compared to the conductivity of the substrate.

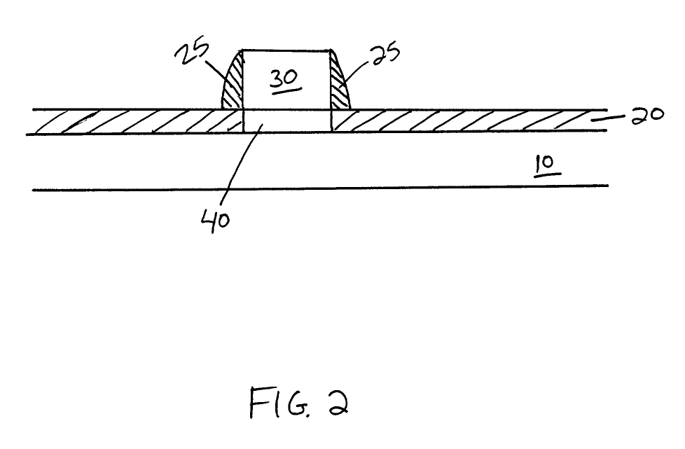

FIG. 2 shows a cross section of an alternative structure for the present invention in which the high-density material 20 is deposited after device formation but prior to implantation to permit the creation of the source/drain region during a lightly doped deposition. A layer of silicon-containing material, which may be patterned and etched to form gate structure 30, is formed on a standard gate dielectric 40. Gate dielectric 40 may be made of an oxide, thermally grown SiO₂, a nitride, an oxynitride or any combination thereof, and is generally on the order of 1 to 10 nm thick. The gate structure 30 on the gate dielectric 20 may have sidewalls 25.

The present invention may be implemented with current integrated circuit technologies that use pocket implants to reduce the effect of the short transistor gate length on transistor properties such as threshold voltage. The effect of a pocket implant is not limited to threshold voltage. A pocket implant for a particular transistor type usually results in a doping profile that extends beyond the source/drain extension of the transistor.

By using a high-density material as a type of implant hard mask prior to the implantation, heavier atoms in the high-density layer enhance the stopping power of the material, allowing higher implantation energies during doping with a resulting increase in reliability and efficiency. A shallow junction is created because the high-density screening layer reduces the impinging energy of the implanted atoms, using implantation energies in current use.

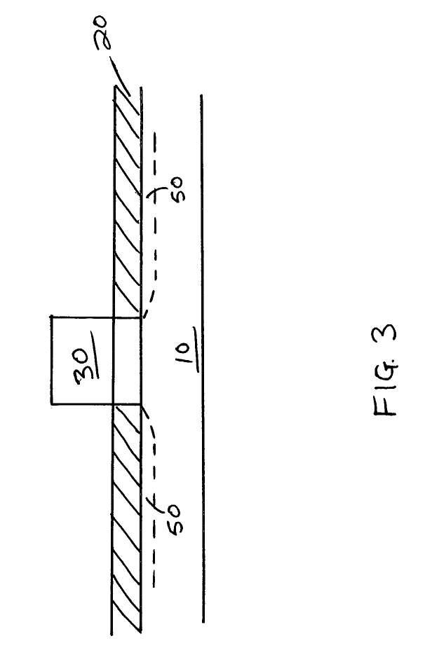

As depicted in FIG. 3, the present invention further provides for the use of conventional implantation machinery and methods for the formation of ultra-shallow junctions. The substrate 10 is implanted, using standard implantation techniques, to form source/drain regions 50. The use of existing techniques also extends the life of current equipment resulting in significant savings in equipment costs.

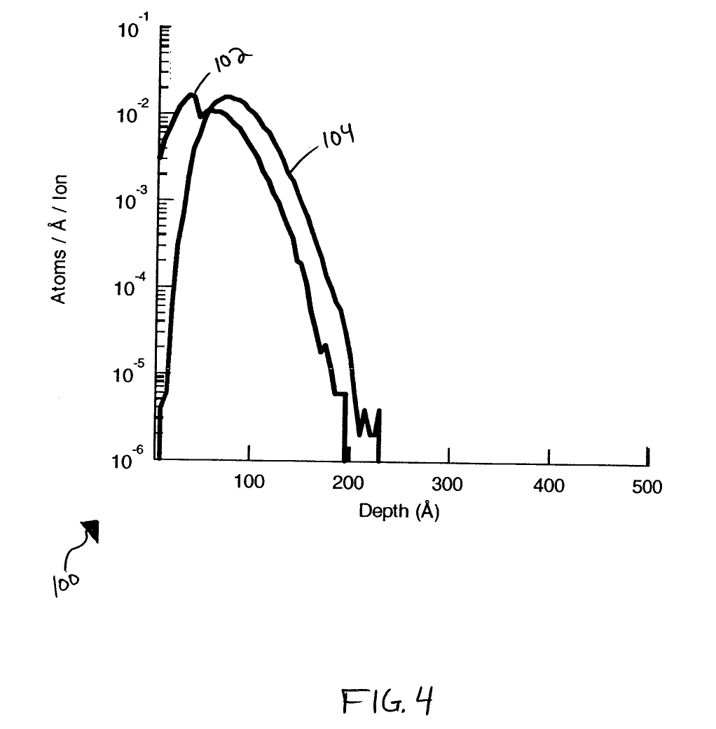

FIG. 4 is a graph illustrating one aspect of the present invention. Plot 100 of FIG. 4 depicts plotline 102, representing implantation depth achieved according to the present invention using, for example, HfSiO₄ over Si at 5 KeV. In comparison, plotline 104 represents depth achieved using conventional SiO₂ over Si at 5 KeV.

According to the present invention, implantation takes place over 40 angstroms of the high-density material, in comparison to SiO₂. As plot 100 demonstrates, the implantation of the dopant, in atoms per Angstrom per ion, was shallower with the high-density material mask implantation of the present invention as represented by plotline 102. This provides increased gate efficiency and increased speed.

While this invention has been described with reference to illustrative embodiments, it is not intended that this description be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

What is claimed is:

1. A method of fabricating an integrated circuit having a gate, comprising the steps of:
depositing a high density material on a substrate about a gate; and
implanting a lightly doped drain through the high-density material to create a shallow drain.

2. The method of claim 1, wherein the gate comprises a gate oxide comprising a material selected from the group consisting of: silicon dioxide, silicon oxynitride, silicon nitride, and any combination thereof.

3. The method of claim 1, wherein the gate comprises a material selected from the group consisting of: doped polysilicon, undoped polysilicon, epitaxial silicon, polysilicon germanium, metallic layers, and any combination thereof.

4. The method of claim 1, wherein the high-density material is selected from the group consisting of: Hf silicate, HfO₂, HfSiOₓ, Zirconium silicates and oxides, aluminum oxides, HfON, HfSiON, and any combination thereof.

5. The method of claim 1, further comprising the step of implanting the substrate adjacent to the gate to form a source/drain region.

6. The method of claim 1, wherein the thickness of the high-density material is varied to adjust the depth of implantation.

7. The method of claim 1, wherein the implantation is at high energy.

8. The method of claim 1, wherein deposition of the high-density material is by chemical vapor deposition.

9. A method of producing a semiconductor device having a gate, comprising the steps of:
depositing a high-density material on a substrate at a gate; and
implanting a lightly doped drain through the high-density material to create a shallow drain about the gate to form a source/drain region.

10. The method of claim 9, wherein the gate comprises a gate oxide comprising a material selected from the group consisting of: silicon dioxide, silicon oxynitride, silicon nitride, and any combination thereof.

11. The method of claim 9, wherein the gate comprises a material selected from the group consisting of: doped polysilicon, undoped polysilicon, epitaxial silicon, polysilicon germanium, metallic layers, and any combination thereof.

12. The method of claim 9, wherein the high-density material is selected from the group consisting of: Hf silicate, HfO₂, HfSiOₓ, Zirconium silicates and oxides, aluminum oxides, HfON, HfSiON, and any combination thereof.

13. The method of claim 9, wherein the thickness of the high-density material is varied to adjust the depth of implantation.

14. The method of claim 9, wherein the implantation is at high energy.

15. The method of claim 9, wherein deposition of the high-density material is by chemical vapor deposition.

16. A method of fabricating an integrated circuit having a gate, comprising the steps of:
depositing material selected from the group consisting of: Hf silicate, HfO₂, HfSiOₓ, Zirconium silicates and oxides, aluminum oxides, HfON, HfSiON, and any combination thereof, on a substrate to form a high-density layer;
depositing a gate on the high-density layer; and
implanting a lightly doped drain through the high-density layer to create a shallow drain to form a source/drain region.

17. The method of claim 16, wherein the gate comprises a gate oxide comprising a material selected from the group consisting of: silicon dioxide, silicon oxynitride, silicon nitride, and any combination thereof.

18. The method of claim 16, wherein the gate comprises a material selected from the group consisting of: doped polysilicon, undoped polysilicon, epitaxial silicon, polysilicon germanium, metallic layers, and any combination thereof.

19. The method of claim 9, wherein the thickness of the high-density layer is varied to adjust the depth of implantation.

20. The method of claim 9, wherein the implantation is at high energy.
